(19) United States
(12) Patent Application Publication
(10) Pub. No.: US 2003/0169081 A1
(43) Pub. Date: Sep. 11, 2003

(54) Impedance controlled double data rate input buffer

(76) Inventors: Zhigang Han, San Jose, CA (US); Cong Q. Khieu, San Jose, CA (US)

Correspondence Address: ZAGORIN O'BRIEN & GRAHAM LLP, 401 W 15TH STREET, SUITE 870, AUSTIN, TX, 78701, US

(21) Appl. No.: 10/090,894

(22) Filed: Mar. 5, 2002

(51) Int. Cl. H03B 1/00

(52) U.S. Cl. 327/108

(57) ABSTRACT

The present invention describes a method and apparatus to reduce the delay variations caused by the process variations in DDR input buffers. The changes in the impedance due to the process variations are used to determine the bias current for the DDR buffers. The bias current is proportional to the changes in the impedance. The bias current is adjusted to maintain small delay variations in the DDR buffers. The delays in the DDR buffers can be adjusted by adjusting the bias current in response to the corresponding impedance changes due to the process variations in the semiconductor devices.

### BACKGROUND OF THE INVENTION

1. Field of the Invention

The present invention relates to driver circuits and more particularly to driver circuits for use in information processing systems.

2. Description of the Related Art

In computer and information processing systems, various integrated circuit chips must communicate digitally with each other over common buses. The signal frequency at which this communication occurs can limit the performance of the overall system. Thus, the higher the communication frequency, the better. The maximum frequency at which a system communicates is a function not only of the time that it takes for the electromagnetic wavefronts to propagate on the bus from one chip to another, but also of the time required for the signals to settle to levels that can be reliably recognized at the receiving bus nodes as being HIGH or LOW, referred to as the settling time.

The operating characteristics of transistors such as CMOS transistors, from which drivers are typically constructed, change under a variety of conditions, often referred to as process, voltage, temperature (PVT) variations. PVT variations may be conceptualized as a box across which the operating characteristics of the transistors move. For example, the operating characteristics may move from a fastest comer of PVT variations to a slowest comer of PVT variations, and everywhere in between. More specifically, the operating characteristics due to PVT variations may change with variations in manufacturing process as well as with variations in operating conditions such as junction temperature and supply voltage levels. The operating characteristics may also change with variations of voltage differences across the transistor terminals of the driver; the voltage differences may change as the voltage level at the output node of the driver changes.

FIG. 1A illustrates an example of prior art architecture of DDR buffer system. A source follower 110 transfers an input voltage received on link 105 to an output voltage value required for the following stage of the circuit. A voltage reference 120 is coupled to source follower by a link 125. Voltage reference 120 supplies independent stable reference voltage for source follower 110. Voltage reference 120 is also coupled to a hysteresis comparator 130 via link 125. Source follower 110 uses independent stable reference voltage from voltage reference 120 to provide the bias current, and output the required voltage value for the circuit that follows source follower 110. Source follower 110 provides output voltage on link 115 that is proportional to the input signals. The value of output voltage can be configured to be adequate for the next stage, the hysteresis comparator 130.

Hysteresis comparator 130 is coupled to source follower 110 via link 115. Hysteresis comparator 130 compares two analog signals and outputs a binary signal based on the comparison. Hysteresis comparator 130 changes the input threshold as a function of the input voltage level, which improves the response of hysteresis comparator in a noisy environment. Hysteresis comparator 130 is coupled to a level shifter 140 via a link 135. Level shifter 140 extends the input signal range so the signal can swing from ground to voltage supply, which makes the signal a clear digital signal. Level shifter 140 is coupled to a buffer 150 via a link 145. Buffer 150 can be any buffer (e.g., DDR buffer). The methods of designing source follower, reference voltage, hysteresis comparator and level shifter are known in the art.

If inadequate compensation is made for PVT variations in the design, the amount of time the driver takes to switch can vary substantially within a particular driver as well as from driver to driver on a chip. The process variations can cause delay through buffers. For example, in a double data rate (DDR) input buffer system (e.g. system 100), the delay between the fastest corner of PVT to a slowest corner of PVT can be 650 pico seconds. This delay limits the clock frequency that can be used in the DDR input buffers. A method and apparatus is needed to compensate for the delays caused by the changes in the impedance due to the process variations.

### SUMMARY

In one embodiment, the present invention describes a method and apparatus for managing an input buffer in an integrated circuit. The method includes determining one or more process related variations in input impedance of the integrated circuit and generating a bias current based on the process related variation in input impedance. According to an embodiment, the input impedance is determined by an average code generator and the bias current is generated by a bias current unit. The method further includes generating one or more impedance codes based on the process related variations in input impedance of the integrated circuit and using the impedance codes to generate the bias current.

The method further includes receiving an input signal adjusting a voltage of the input signal with respect to a reference signal, comparing the input signal to the bias current, and generating a resulting signal. The method further includes adjusting a level of the resulting signal and forwarding the resulting signal to the input buffer.

The foregoing is a summary and thus contains, by necessity, simplifications, generalizations and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The present invention may be better understood, and numerous objects, features, and advantages made apparent to those skilled in the art by referencing the accompanying drawing.

FIG. 1A illustrates an example of prior art architecture of DDR buffer system.

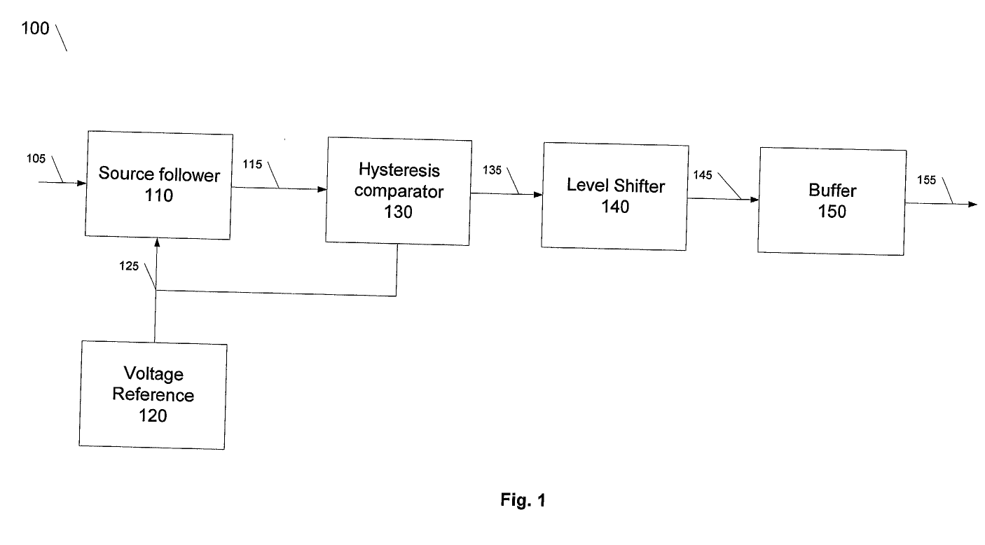

FIG. 2A illustrates an example of an architecture of impedance controlled DDR buffer system according to an embodiment of the present invention.

FIG. 2B illustrates an example of a variation in the architecture of impedance controlled DDR buffer system according to an embodiment of the present invention.

### DETAILED DESCRIPTION OF THE INVENTION

The following is intended to provide a detailed description of an example of the invention and should not be taken to be limiting of the invention itself. Rather, any number of variations may fall within the scope of the invention which is defined in the claims following the description.

Introduction

The present invention describes a method and apparatus to reduce the delay variation caused by the process variations in DDR input buffers. The changes in the impedance due to the process variations are used to determine the bias current for the DDR buffers. The bias current is proportional to the changes in the impedance. The bias current is adjusted to maintain small delay variations due to PVT. The delays in the DDR buffers can be adjusted by adjusting the bias current in response to the corresponding impedance changes due to the process variations.

System Architecture

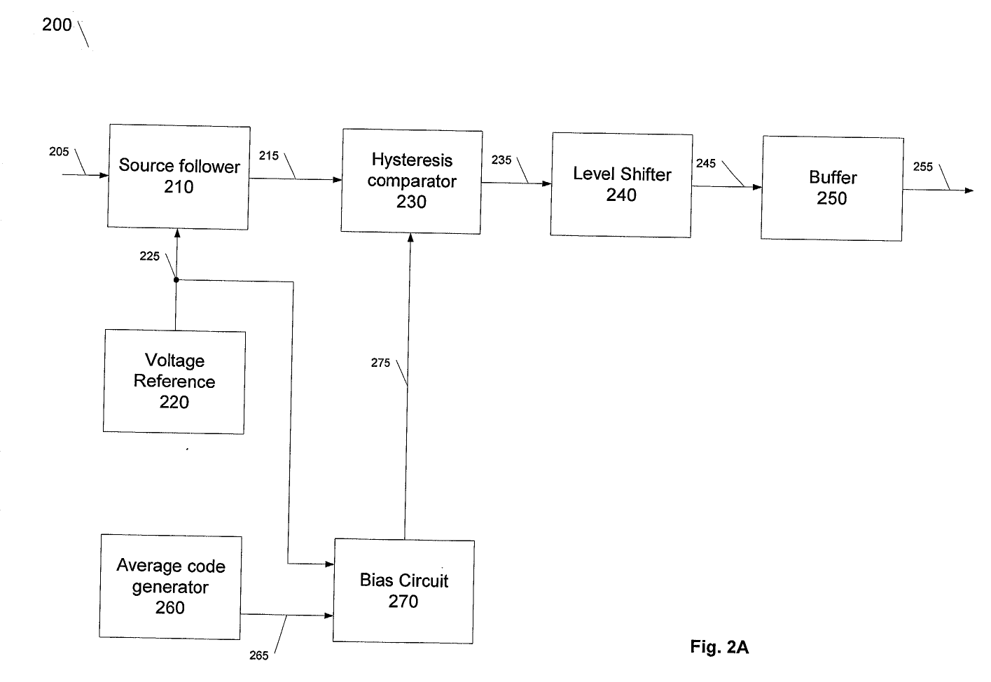

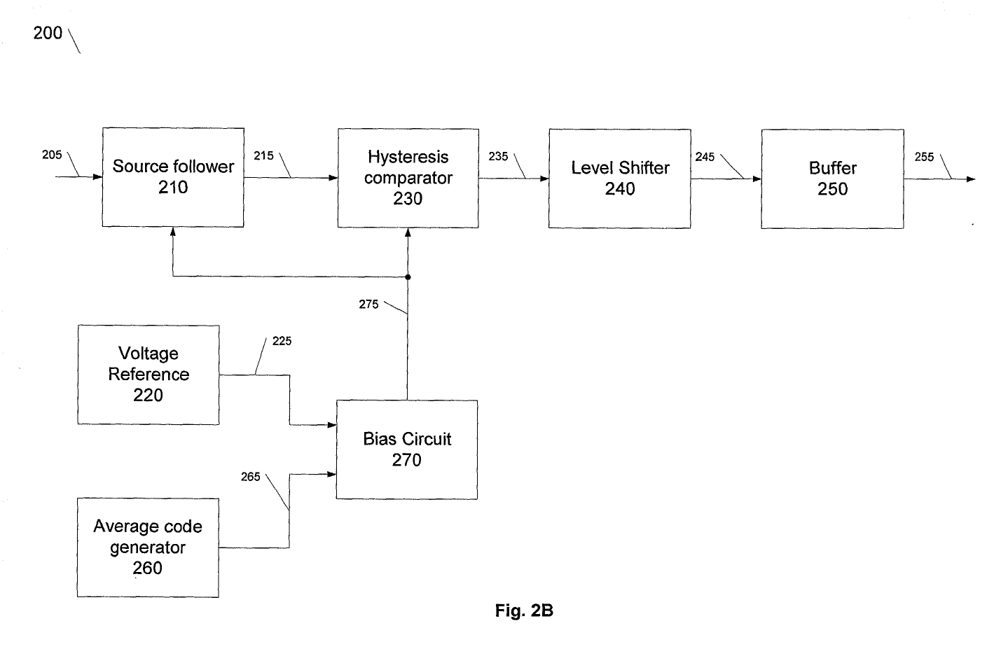

FIG. 2A illustrates an example of an architecture of impedance controlled DDR buffer system 200 according to an embodiment of the present invention. A source follower 210 transfers an input voltage received on link 205 to an output voltage value required for the following stage. A voltage reference 220 is coupled to source follower by a link 225. Voltage reference 220 supplies independent stable reference voltage for source follower 210. Source follower 210 can use independent stable reference voltage from voltage reference 220 to output the required voltage value for the circuit that follows source follower 210. Source follower 210 also receives a logic reference from the system on link 205.

The logic reference is used to determine the level of an input signal received on link 205. The DDR input buffer generates a logic output representing the level of the input signal with respect to the logic reference (e.g., “1” to represent higher signal level and “0” to represent lower signal level or vise versa). The reference logic level can be predetermined during the system design. Source follower 210 provides output voltages on link 215 for the next stage, comparator 230. The output voltages are adjusted by source follower 210 to provide adequate voltage level for comparator 230.

A hysteresis comparator 230 is coupled to source follower 210 via link 215. Hysteresis comparator 230 compares two analog signals and outputs a binary signal based on the comparison. Hysteresis comparator 230 changes the input threshold as a function of the input voltage level, which improves the response of hysteresis comparator in a noisy environment. Hysteresis comparator 230 is coupled to a level shifter 240 via a link 235. Level shifter 240 extends the input signal range so the signal can swing from ground to voltage supply, which makes the signal a clear digital signal. Level shifter 240 is coupled to a buffer 250 via a link 245. Buffer 250 can be any buffer (e.g., DDR buffer). The methods of designing source follower, reference voltage, hysteresis comparator and level shifter are known in the art.

An average code generator 260 is coupled to a bias circuit 270 via a link 265. Voltage reference 120 is coupled to bias circuit 170 via link 125. Average code generator 260 is a binary code generator. Average code generator 260 generates predetermined binary codes for bias circuit 270. Bias circuit 270 generates predetermined amount of bias current proportional to the binary codes provided by average code generator 260. Average code generator receives input from an impedance controller. The impedance controller can be configured using techniques known in the art.

The impedance controller generates control codes to adjust the output impedance to compensate for process, supply voltage and temperature variations. The impedance controller generates pull-down and pull-up codes. Average code generator 260 can use the pull-down and pull-up codes provided by the impedance controller to generate predetermined binary codes to reflect the impedance changes due to the process variations. Bias circuit 270 is coupled to hysteresis comparator 230 via a link 275. Bias circuit 270 provides additional bias current to hysteresis comparator 230. The additional bias current is proportional to the changes in the impedance of the integrated circuit (e.g., due to processing or the like). Bias circuit 270 can receive impedance codes generated by average code generator 260 to output appropriate bias current for hysteresis comparator 230 to compensate changes in the impedance of the integrated circuit. The change in the impedance of the integrated circuit is proportionally reflected in the bias current provided by bias circuit 270. Thus, the characteristics of buffer 250 can be dynamically maintained after the integrated circuit processing. The links described herein (e.g., links 205, 215, 225, 235, 245, 265, 275 or the like) can include one or more communication paths as needed for circuit interfaces.

FIG. 2B illustrates an example of a variation in the architecture of impedance controlled DDR buffer system 200 according to an embodiment of the present invention. In this embodiment, voltage reference 220 is not coupled to source follower 210. Bias circuit 270 provides stable voltage reference for hysteresis comparator 230 and source follower 210.

Due to the process variations, the circuit can perform differently in different integrated circuits. To maintain similar circuit performance, different bias current is needed to compensate for process variations. Table 1 illustrates an example the values of the circuit delay according to an embodiment of the present invention.

TABLE 1
An example of bias current and circuit delay according
to an embodiment of the present invention.

| Bias current value (micro amperes) | Delay (nano seconds) |
|---|---|
| 195 | 1.126 at ffhl |
| 86 | 1.774 at sslh |

In the present example, the simulation shows 0.648 nano seconds in the circuit delay between the fastest comer of the device (ffhl) and the slowest comer of the device (sslh). The bias current also changes with PVT variations and is measured by simulating the circuit. Table 2 illustrates an example of bias current generated in response to the codes received from the average code generator according to an embodiment of the present invention.

TABLE 2
An example of bias current and circuit delay in response to average
code according to an embodiment of the present invention.

| Code | Bias current value | Delay |
|---|---|---|
| received | (micro amperes) | (nano seconds) |
| 0000 | 31 | 1.458 at ffhl |
| 1111 | 77 | 1.5l8 at sslh |

In the example illustrated in Table 2, the bias current is narrowly tailored to address the PVT changes reflected by the code. The difference in the delay variations between ffhl and sslh is 0.060 nano seconds which is much smaller then the delay difference shown in Table 1. The bias current values are generated by a bias circuit (e.g., bias circuit 270 or the like) in response to the codes generated by the average code generator 260 representing PVT variations according to an embodiment of the present invention. The value of bias current depicted in Table 2 can be determined using simulation technique known in the art in response to various PVT changes. Similarly, various bias current values can be configured in response to different codes for specific applications. While specific codes and bias current values are shown for illustration purpose, one skilled in art will appreciate that any representation can be use to reflect the impedance changes due to the process variation and any desired value of bias current can be generated using the impedance codes.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims.

What is claimed is:

1. An impedance controlled buffer system comprising:
an average code generator;
a bias circuit coupled to said average code generator, wherein said bias circuit is configured to generate one or more bias currents.

2. The apparatus of claim 1, wherein said average code generator generates one or more impedance control codes.

3. The apparatus of claim 1, wherein said bias circuit generates said bias current in response to said impedance control codes.

4. The apparatus of claim 1, wherein said bias current is generated to compensate for process variations of a semiconductor device.

5. The apparatus of claim 1, wherein one or more values of said bias current for said impedance control codes are predetermined.

6. The apparatus of claim 1, further comprising:
a hysteresis comparator coupled to said bias circuit, wherein said hesteresis comparator is configured to compare two or more analog input signals and generate a binary signal based on the comparison.

7. The apparatus of claim 1, further comprising:
a source follower unit coupled to said hysteresis comparator, wherein said source follower unit is configured to adjust an incoming voltage for said hysteresis comparator.

8. The apparatus of claim 1, further comprising:
a voltage reference unit coupled to said source follower unit, said voltage reference unit is configured to provide a reference voltage.

9. The apparatus of claim 8, wherein said reference voltage is predetermined.

10. The apparatus of claim 1, wherein said reference voltage unit is coupled to said bias circuit.

11. The apparatus of claim 1, wherein said bias circuit is coupled to said source follower unit.

12. The apparatus of claim 1, further comprising:
a level shifter coupled to said hysteresis comparator, wherein said level shifter is configured to adjust a voltage level of said binary signal.

13. The apparatus of claim 12, wherein said adjusting said voltage level of said binary signal allows said binary signal to swing between a ground value to said reference value.

14. The apparatus of claim 1, further comprising:
a buffer, coupled to said level shifter.

15. The apparatus of claim 1, wherein said bias circuit is further configured to provide said reference voltage to said hyestereis comparator.

16. A method of managing an input buffer in an integrated circuit comprising:
determining one or more process related variations in input impedance of said integrated circuit; and
generating a bias current based on said process related variation in input impedance.

17. The method of claim 16, wherein said input impedance is determined by an average code generator.

18. The method of claim 16, wherein said input buffer is a double data rate input buffer.

19. The method of claim 16, wherein said bias current is generated by a bias current unit.

20. The method of claim 16, further comprising:
generating one or more impedance codes based on said process related variations in input impedance of said integrated circuit; and
using said impedance codes to generate said bias current.

21. The method of claim 20, farther comprising:
receiving an input signal;
adjusting a voltage of said input signal with respect to a reference signal.

22. The method of claim 21, wherein said reference voltage signal is predetermined.

23. The method of claim 21, farther comprising:
comparing said input signal to said bias current; and
generating a resulting signal.

24. The method of claim 23, further comprising:
adjusting a level of said resulting signal; and
forwarding said resulting signal to said input buffer.

25. A system for managing an input buffer in an integrated circuit comprising:
means for determining one or more process related variations in input impedance of said integrated circuit; and
generating a bias current based on said process related variation in input impedance.

26. The system of claim 25, wherein said input impedance is determined by an average code generator.

27. The system of claim 25, wherein said input buffer is a double data rate input buffer.

28. The system of claim 25, wherein said bias current is generated by a bias current unit.

29. The system of claim 25, further comprising:
means for generating one or more impedance codes based on said process related variations in input impedance of said integrated circuit; and
using said impedance codes to generate said bias current.

30. The system of claim 29, further comprising:
means for receiving an input signal;
means for adjusting a voltage of said input signal with respect to a reference signal.

31. The system of claim 30, wherein said reference voltage signal is predetermined.

32. The system of claim 30, further comprising:
means for comparing said input signal to said bias current; and
means for generating a resulting signal.

33. The system of claim 32, further comprising:
means for adjusting a level of said resulting signal; and
means for forwarding said resulting signal to said input buffer.
